(19) United States
(12) Patent Application Publication
(10) Pub. No.: US 2023/0371381 A1
(43) Pub. Date: Nov. 16, 2023

(54) DEVICES AND METHODS FOR GENERATING ELECTRICAL ENERGY

(71) Applicant: entX Limited, Adelaide (AU)

(72) Inventors: Bryn Jones, Biggs Flat (AU); Julian Frederick Kelly, Robe (AU)

(21) Appl. No.: 18/025,494

(22) PCT Filed: Sep. 9, 2021
(86) PCT No.: PCT/AU2021/051044

§ 371 Date: Mar. 9, 2023

(30) Foreign Application Priority Data
Sep. 10, 2020 (AU) 2020903248

(51) Int. Cl. H10N 10/851

(52) U.S. Cl. CPC H10N 10/851

(57) ABSTRACT

The present disclosure related to devices for generating electrical energy, methods for generating electrical energy, and methods for producing devices for generating electrical energy. In certain embodiments, the present disclosure provides an electrical energy generating device, the device comprising at least one electrical cell comprising an asymmetric pair of metal-semiconductor junctions to produce an electric potential difference to capture thermally excited charge carriers within the semiconductor.

### PRIORITY CLAIM

This application claims priority to Australian Provisional Patent Application 2020903248 filed on 10 Sep. 2020, the contents of which are hereby incorporated by reference.

### FIELD

The present disclosure relates to devices for generating electrical energy, methods for generating electrical energy, and methods for producing devices for generating electrical energy.

The use of electrochemical devices for generating electrical energy is widespread. These devices rely on conventional chemical reactions to provide electrical power, but as such are subject to the use of the chemical reactants to provide their energy, and have limitations in their useable life in the absence of recharging or refuelling. Rechargeable electrochemical devices are able to extend the useable life of electrochemical energy devices, but also suffer a number of their own limitations, not least that the devices lose their ability to be recharged over time.

Thermovoltaic devices convert thermal energy to electricity. A number of such types of devices have been developed with the promise of providing a source of electricity from an available passive energy source. Such devices are particularly attractive as they do not require a built-in energy source and they may operate under conditions where excess thermal energy is readily available, such as sources of geothermal energy or industrial waste energy.

Thermovoltaic devices have also attracted significant interest in fields where long term power output is required, or where it is not practical to change or service the power source. The devices also have no moving parts, and typically require little or no maintenance. These properties make thermovoltaic systems suitable for remote-site and portable electricity-generating applications, or applications where large amounts of heat are produced and yet not efficiently captured. Thermovoltaic systems also provide an alternative system to capturing energy through the boiling of liquids and recovering energy from the resulting vapour using mechanical means.

However, despite the promise of utilising thermovoltaic energy, the technology has not been widely applied, in part due to one or more of the cost of manufacture, difficulty of manufacturing requisite materials, low conversion efficiencies, the need for exotic materials, and the need for high temperature sources of thermal energy providing large amounts of radiant heat.

The present disclosure relates to thermovoltaic devices which utilise asymmetric metal-semiconductor junctions to capture thermally excited charge carriers in a suitable semiconductor.

### SUMMARY

The present disclosure relates to devices for generating electrical energy, methods for generating electrical energy, and methods for producing devices for generating electrical energy.

Certain embodiments of the present disclosure provide an electrical energy device, the device comprising at least one electrical cell comprising an asymmetric pair of metal-semiconductor junctions to produce an electric potential difference to capture thermally excited charge carriers within the semiconductor.

Certain embodiments of the present disclosure provide an electrical energy generating device, the device comprising at least one electrical cell comprising:
first and second closely spaced electrodes, the first electrode comprising a low work function metal material and the second electrode comprising a high work function metal material; and
disposed between the first and second electrodes, a semiconductor capable of producing charge carriers in response to thermal excitation.

Certain embodiments of the present disclosure provide a method of generating electricity, the method comprising using a device as described herein to generate the electricity.

Certain embodiments of the present disclosure provide a method of generating electrical energy, the method comprising:
producing an electric potential difference using an asymmetric pair of metal-semiconductor junctions;
producing charge carriers within the semiconductor by thermal excitation, the charge carriers being mobile under the effect of an electric field; and
capturing the charge carriers into an external circuit using the electrical potential difference;
thereby generating electrical energy.

Certain embodiments of the present disclosure provide a method of generating electrical energy, the method comprising:
producing an electric potential difference between first and second closely spaced electrodes, the first electrode comprising a low work function metal material and the second electrode comprising a high work function metal material;
producing charge carriers within a semiconductor disposed between the electrodes by thermal excitation, the charge carriers being mobile under the effect of an electric field; and
capturing the charge carriers into an external circuit using the electric field existing between the electrodes;
thereby generating electrical energy.

Certain embodiments of the present disclosure provide a method of generating electrical energy, the method comprising:
producing an electric field between first and second closely spaced electrodes, the first electrode comprising a low work function metal material and the second electrode comprising a high work function metal material, the electric field being produced due to different types of metal-semiconductor junctions at the two different electrodes;
producing charge carriers by thermal excitation, the charge carriers being mobile under the effect of an electric field; and
capturing the charge carriers into an external circuit using the electric field existing between the electrodes;
thereby generating electrical energy.

Certain embodiments of the present disclosure provide a device for generating electrical energy using a method as described herein.

Certain embodiments of the present disclosure provide a method of producing an electrical energy generating device, the method comprising incorporating an asymmetric pair of metal-semiconductor junctions into the device, wherein the semiconductor is capable of producing charge carriers in response to thermal excitation.

Certain embodiments of the present disclosure provide a method of producing an electrical energy generating device, the method comprising incorporating one or more electrical cells into the device, the one or more electrical cells comprising first and second closely spaced electrodes, the first electrode comprising a low work function metal material and the second electrode comprising a high work function metal material, and disposed between the first and second electrodes a semiconductor capable of producing charge carriers in response to thermal excitation.

Certain embodiments of the present disclosure provide an electrical generating device produced by a method as described herein.

Other embodiments are disclosed herein.

### DETAILED DESCRIPTION

The present disclosure relates to devices for generating electrical energy, methods for generating electrical energy, and to methods for producing devices for generating electrical energy.

The present disclosure is based on the recognition that electrical energy may be generated using a device utilising asymmetric metal-semiconductor junctions for generating an electric potential for collecting charge carriers which may be produced by thermal excitation in the semiconductor. Charge carriers are produced in low-band gap semiconductors upon excitation by thermal energy. The charge carriers generated within the semiconductor are mobile under the effect of an electric field created by the asymmetric metal-semiconductor junctions and are swept into an external circuit using the built-in electric potential difference.

Certain embodiments of the present disclosure are directed to products and methods that have one or more combinations of advantages. For example, some of the advantages of some of the embodiments disclosed herein include one or more of the following: new and/or improved devices for generating electrical energy; new methods for converting thermal energy into electrical energy; using thermal energy for directly generating electrical energy; producing devices able to provide electrical power for specialised remote power requirements where a thermal energy source is available; the use of asymmetric metal-semiconductor-metal junctions in a sandwich structure in which the thermally excitable semiconductor sits between the junctions; the use of polymers and/or polymeric composite materials as thermally excitable semiconductors in an electrical energy generating device, and which provide manufacturing and cost benefits; the use of an energy generating structure which is well suited for the stacking of multiple cells to achieve improvements in power output; the use of an energy generating structure which is flexible in terms of being able to tailor the thickness of the semiconductor, thereby allowing optimisation of the device for a particular application; the use of an energy generating structure which obviates the need to work with carefully engineered thermal emitters; electrical energy devices which have a low cost of manufacture; ease of manufacture of electrical energy devices; the amenability of the materials used to produce electrical cells to allow scalable, automated manufacturing methods; to address one or more problems and/or to provide one or more advantages, or to provide a commercial alternative. Other advantages of certain embodiments of the present disclosure are also disclosed herein.

Certain embodiments of the present disclosure provide an electrical energy generating device.

In certain embodiments, the present disclosure provides an electrical energy generating device, the device comprising at least one electrical cell comprising an asymmetric pair of metal-semiconductor junctions to produce an electric potential difference to capture thermally excited electron hole pairs within the semiconductor.

It will be appreciated that the device of the present disclosure may also be referred herein to in some embodiments as a “thermovoltaic device”.

In certain embodiments, the present disclosure provides a thermovoltaic device, the device comprising at least one electrical cell comprising an asymmetric pair of metal-semiconductor junctions to produce an electric potential difference to capture thermally excited electron hole pairs within the semiconductor.

The term “cell” as used herein refers to a functional unit for generating electrical energy.

In certain embodiments, the device comprises more than one cell. In certain embodiments, the device comprises multiple cells. In certain embodiments, the device comprises a plurality of cells. A suitable number of cells may be selected based on the desired characteristics of the device required. Methods for electrically connecting individual cells to achieve current flow are known in the art.

It will be appreciated that the term “metal-semiconductor junction” as used herein also includes within its scope an interface that can be described as a Schottky junction for either electrons or holes, and whilst the specification generally refers to a “metal-semiconductor junction” as a term of the art, it will be appreciated that other types of material-semiconductor junctions are contemplated, and may for example be a junction between a non-metal and a semiconductor.

In certain embodiments, one of the metal-semiconductor junctions comprises a junction in which the semiconductor at the interfacial region has a depleted electron population and the other metal-semiconductor junction comprises a junction in which the semiconductor at the interfacial region has an enhanced electron population.

In certain embodiments, one of the metal-semiconductor junctions comprises a low work function material and the other metal-semiconductor junction comprises a high work function material.

In certain embodiments, one of the metal-semiconductor junctions comprises a low work function metal material and the other metal-semiconductor junction comprises a high work function metal material.

The term “metal” as used herein refers to a metal containing material and includes for example a material including one or more metals, an alloy, an intermetallic compound, or a cermet. Other types of materials may be included in the metal material.

Methods for determining the work function of a material are known in the art and include methods employing electron emission from a sample, as induced by photon absorption (photoemission), by high temperature (thermionic emission), by an electric field (field emission), or by use of a Kelvin Probe measurement. Relative methods make use of the work function difference between a sample and a reference metal.

Low work function materials and high work function materials are commercially available and/or may be produced by a method known in the art.

In certain embodiments, the low work function material comprises a low work function metal material.

In certain embodiments, the low work function material comprises a metal and/or an intermetallic compound.

In certain embodiments, the low function metal material is a substantially pure elemental metal. In certain embodiments, the low work function metal material comprises two or more metals. In certain embodiments the low work function metal material comprises a mixture of metals. In certain embodiments, the low work function material comprises a cermet. In certain embodiments, the low work function material comprises one or more metals and other materials. In certain embodiments, the low work function material is an alloy.

In certain embodiments, the low work function material comprises a material with a work function of less than 4.0 eV.

In certain embodiments, the low work function material comprises a material with a work function of 3.5 eV or less. In certain embodiments, the low work function material comprises a material with a work function in the range of 2.5 to 3.5 eV.

In certain embodiments, one of the metal-semiconductor junctions comprises at its interface or junction a low work function metal material comprising one or more of europium, strontium, barium, samarium, dysprosium, neodymium, gadolinium, terbium, holmium, erbium, thulium, lanthanum, scandium, thorium, calcium, magnesium, cerium, yttrium, ytterbium, sodium, lithium, potassium, rubidium, hafnium, and cesium. These low work function materials are commercially available and/or may be produced by a method known in the art.

In certain embodiments, one of the metal-semiconductor junctions comprises samarium metal.

Examples of other low work function materials include Ag—O—Cs, W—O—Ba, Sc₂O₃ and LaB₆, all of which are commercially available or may be produced by a method known in the art.

In certain embodiments, the high work function material comprises a metal and/or an intermetallic compound.

In certain embodiments, one of the metal-semiconductor junctions comprises at its interface or junction a high work function material comprising one or more of nickel, platinum, silver, gold, aluminium, cobalt, chromium, copper, beryllium, bismuth, cadmium, iron, gallium, germanium, mercury, indium, iridium, manganese, molybdenum, niobium, osmium, lead, palladium, rhenium, rhodium, ruthenium, antimony, silicon, tin, tantalum, technetium, titanium, vanadium, tungsten, zinc and zirconium. These high work function materials are commercially available and/or may be produced by a method known in the art.

In certain embodiments, one of the metal-semiconductor junctions comprises nickel metal.

In certain embodiments, the high work function material comprises a material with a work function of greater than 4.0 eV. In certain embodiments, the high work function material comprises a chemical element with a work function of greater than 4.0 eV.

In certain embodiments, the high work function material comprises a high work function metal material.

In certain embodiments, the high work function metal material is a substantially pure elemental metal. In certain embodiments, the high work function metal material comprises two or more metals. In certain embodiments the high work function metal material comprises a mixture of metals. In certain embodiments, the high work function material comprises one or more metals and other materials. In certain embodiments, the high work function material is an alloy.

In certain embodiments, the material with a high work function comprises an electrically conductive non-metal, for example indium tin oxide.

In certain embodiments, the material with a high work function comprises a composite material.

In certain embodiments, the asymmetric pair of metal-semiconductor junctions is formed from two closely-spaced electrodes of different composition in contact with the semiconductor, one of the electrodes comprising a low work function material and the other electrode comprising a high work function material.

In this embodiment, an inter-electrode electric potential is produced between the first and second closely spaced electrodes by virtue of the differing metal-semiconductor junctions at each electrode. Whatever the semiconductor type, as defined by majority charge carrier, a Schottky junction is formed at one of the electrodes, and an ohmic junction is formed at the opposite electrode. Standard definitions of the Schottky and ohmic junctions are known in the art., and relate to how the electric potential changes within the semiconductor with proximity to an electrode. If a potential barrier for majority charge carriers forms close to a metal electrode, it is deemed a Schottky junction and these are formed at high work function metal interfaces with n-type semiconductors. If the potential close to the electrode becomes more attractive for majority charge carriers it is deemed an ohmic junction and these can form at low work function metal interfaces with n-type semiconductors if the Fermi level of the semiconductor is higher than that of the metal. In the optimal case, the electric potential associated with the two differing junctions reinforce each other to provide a sizable macroscopic electric potential capable of collecting many charge-carriers into an external circuit.

In certain embodiments, the low work function material of one electrode comprises a low work function metal material.

In certain embodiments, the low work function metal material of one electrode comprises one or more of europium, strontium, barium, samarium, dysprosium, neodymium, gadolinium, terbium, holmium, erbium, thulium, lanthanum, scandium, thorium, calcium, magnesium, cerium, yttrium, ytterbium, sodium, lithium, potassium, rubidium, hafnium, and cesium.

In certain embodiments, the low work function metal material of one electrode comprises samarium metal.

In certain embodiments, the high work function material of one electrode comprises a high work function metal material.

In certain embodiments, the high work function material of one electrode comprises a metal and/or an intermetallic compound.

In certain embodiments, the high function material of one electrode is a substantially a pure elemental metal. In certain embodiments, the high work function material comprises two or more metals. In certain embodiments, the high work function material comprises one or more metals and other materials. In certain embodiments, the high work function material is an alloy.

In certain embodiments, the high work function metal material of one electrode comprises one or more of nickel, platinum, silver, gold, aluminium, cobalt, chromium, copper, beryllium, bismuth, cadmium, iron, gallium, germanium, mercury, indium, iridium, manganese, molybdenum, niobium, osmium, lead, palladium, rhenium, rhodium, ruthenium, antimony, silicon, tin, tantalum, technetium, titanium, vanadium, tungsten, zinc and zirconium.

In certain embodiments, the high work function metal material of one electrode comprises nickel metal.

In certain embodiments, the material with a high work function comprises an electrically conductive non-metal, for example indium tin oxide.

In certain embodiments, the electrode comprises a ceramic metal composite (ie a cermet material).

In certain embodiments, the high work function material comprises a composite material.

In certain embodiments, the semiconductor is a low band-gap semiconducting material.

In certain embodiments, the semiconductor has a band gap of less than 1.1 eV.

In certain embodiments, the semiconductor comprises one or more of a Group IV semiconductor, a Group III-V compound semiconductor, and a semiconductor containing a Group VI element as a major constituent. Such semiconductors may be obtained commercially or produced by a method known in the art.

In certain embodiments, the semiconductor comprises a compound semiconductor.

The term “compound semiconductor” as used herein refers to a semiconductor composed of at least two different chemical elements, and is typically an intermetallic compound or alloy of different chemical elements, and which has a defined chemical composition and physical structure. The term “Group” as used herein refers to vertical groupings of chemical elements as arranged in the standard periodic table of elements.

In certain embodiments, the Group IV semiconductor comprises a pure Group IV semiconductor or a compound semiconductor. Group IV of the periodic table comprises carbon, silicon, germanium, tin and lead.

In certain embodiments, the Group IV semiconductor comprises germanium, doped germanium; a germanium-tin intermetallic alloy, a germanium-silicon intermetallic alloy, silicon, doped silicon, and a silicon-tin intermetallic alloy.

The term “Group III-V compound semiconductor” comprises a semiconductor formed from one or more of an element from Group III of the periodic table (B, Al, Ga, In, Tl) together with one or more of an element from Group V of the periodic table (N, P, As, Sb, Bi).

In certain embodiments, the Group III-V compound semiconductor comprises a pure nitride, phosphide, arsenide, antimonide, or bismuthide of one or more of aluminium, gallium, indium, and thallium, or a mixed nitride, phosphide, arsenide, antimonide, or bismuthide of one or more of aluminium, gallium, indium, and thallium.

In certain embodiments, the Group III-V compound semiconductor comprises gallium antimonide (GaSb).

In certain embodiments, the semiconductor containing a Group VI element as a major constituent comprises elemental selenium, or comprises a compound semiconductor having a Group VI element as a major constituent. Group VI elements of the periodic table, which are oxygen, sulfur, selenium and tellurium.

In certain embodiments, the semiconductor containing a Group VI element as a major constituent comprises a pure oxide, sulfide, selenide, telluride, or a mixed oxide, sulfide, selenide, telluride, or any combination thereof.

In certain embodiments, the semiconductor comprises thallium sulfide, thallium selenide, thallium telluride, or doped versions thereof.

In certain embodiments, the semiconductor comprises thallium selenide.

In certain embodiments, the semiconductor comprises a composite material.

In certain embodiments, the semiconductor comprises a composite material made from a polymer blended with a solid low band-gap semiconductor. In certain embodiments, the semiconductor comprises a polymer blended with the semiconductor.

In certain embodiments, the polymer comprises an inert polymer. In certain embodiments, the polymer comprises a conducting polymer.

In certain embodiments, the inert polymer comprises one or more of a nylon, a polyimide, a polytetrafluoroethylene, a polypropylene, a polyethylene, a polyvinyl chloride, a polyacrylonitrile, and a polyurethane. The aforementioned polymers are available commercially or may be produced by a method known in the art.

In certain embodiments, the semiconducting material comprises a conducting polymer.

In certain embodiments, the conducting polymer comprises one or more of a polythiophene, a polyacetylene, a polyphenylene vinylene, a polyphenylene sulphide, a polyaniline, a polyvinylacetylene, a polypyrrole, a polyindole, a polyvinylene, a polyazulene, a polyselenophene and an organo-boron polymer. The aforementioned polymers are available commercially or may be produced by a method known in the art.

In certain embodiments, the semiconductor comprises a semiconducting polymer.

In certain embodiments, the semiconducting polymer comprises one or more of a polythiophene, a polyacetylene, a polyphenylene vinylene, a polyphenylene sulphide, a polyaniline, a polyvinylacetylene, a polypyrrole, a polyindole, a polyvinylene, a polyazulene, a polyselenophone, and an organo-boron polymer. Semiconducting polymers are known in the art and are commercially available or may be produced by a method known in the art.

In certain embodiments, the thermally excited charge carriers comprise charge carriers excited by radiative infrared radiation. For example, radiative infrared radiation is produced in large quantities during the production of steel. Methods for capturing thermal energy produced by steel production, are described for example in Frass LM (2014) 40th IEEE Photovoltaic Specialists Conference, Colorado Convention Center, June 2014.

In certain embodiments, the thermally excited charge carriers comprise charge carriers excited by convectively and/or conductively delivered heat. For example, in embodiments of the present disclosure where heat is to be transferred to the semiconductor at the heart of a device, the device may receive the heat by conduction through a bonding plate, and that that plate can also be heated convectively. Methods for providing heat convectively and/or conductively are described for example in Snyder GJ (2008) in “Small thermoelectric generators” The Electrochemical Society Interface 17(3); 54-56.

In certain embodiments, the thermally excited charge carriers comprise charge carriers thermally excited by both radiative infrared radiation and charge carriers thermally excited convectively or conductively.

Examples of sources of thermal energy include geothermal energy, thermal energy derived from manufacturing sources (such as smelting of metals), thermal energy derived from nuclear fission, thermal energy derived from focussed solar radiation, and waste heat produced during industrial processes.

In certain embodiments, the source of thermal energy comprises thermal energy from a suitable radioactive source.

In certain embodiments, the source of thermal energy comprises thermal energy from a suitable radioactive source incorporated into one or more of the first electrode, the second electrode and the semiconductor. In certain embodiments, the source of thermal energy comprises thermal energy from a suitable radioactive source embedded into the device.

For example, ²⁰⁴Tl may be used to generate thermal energy in the semiconductor. In this case, the ²⁰⁴Tl may be used in a thallium containing material used in the semiconductor, and/or doped into a material used in the semiconductor, such as an inert or conducting polymer as described herein.

An electrical cell utilising an asymmetric pair of metal-semiconductor junctions as described herein may be produced by a person skilled in the art.

As described herein, in certain embodiments the electrical energy generating device comprises two closely-spaced electrodes of different composition in contact with the semiconductor.

The dimensions of the first and second electrodes may be selected based on the properties of the materials used in the electrodes and the desired characteristics of the electrical energy generating device.

In certain embodiments, the first and second electrodes are separated by a distance in the range from 0.3 to 100 micrometres. In certain embodiments, the first and second electrodes are separated by a distance in the range from 0.5 to 30 micrometres. Other distances are contemplated.

In certain embodiments, the semiconductor is provided in contact with, deposited on, coated onto, or fused onto the first and/or second electrodes. In certain embodiments, the material is provided in contact with, deposited on, coated onto, or fused onto the first electrode. In certain embodiments, the material is provided in contact with, deposited on, coated onto, or fused onto the second electrode. In certain embodiments, the material is provided in contact with deposited on, coated onto, or fused onto both electrodes.

In certain embodiments, the semiconductor is deposited on an electrode by a vapour deposition process. Methods for using vapour deposition are known in the art. In certain embodiments, the semiconductor is in a form suitable for application to an electrode by a wet application process. Wet application processes are also known in the art. Other processes are contemplated.

In certain embodiments, the device comprises a plurality of electrical cells.

In certain embodiments, the cells are electrically connected in series. In certain embodiments, the cells are electrically connected in parallel. Methods for connecting electrical cells are known in the art.

In certain embodiments, the device comprises a plurality of cells comprising an insulating layer between the cells. Insulating materials are known in the art. In certain embodiments, the insulating layer is a thin film.

In certain embodiments, the present disclosure provides an electrical energy generating device, the device comprising at least one electrical cell comprising an asymmetric pair of metal-semiconductor junctions to produce an electric potential difference to capture thermally excited electron hole pairs within the semiconductor.

In certain embodiments, the present disclosure provides an electrical energy generating device, the device comprising at least one electrical cell comprising:
first and second closely spaced electrodes, the first electrode comprising a low work function metal material and the second electrode comprising a high work function metal material; and
disposed between the first and second electrodes, a semiconductor capable of producing charge carriers in response to thermal excitation.

In certain embodiments, the present disclosure provides a thermovoltaic device, the device comprising at least one electrical cell comprising:
first and second closely spaced electrodes, the first electrode comprising a low work function metal material and the second electrode comprising a high work function metal material; and
disposed between the first and second electrodes, a semiconductor capable of producing charge carriers in response to thermal excitation.

Certain embodiments of the present disclosure provide a method of generating electricity using a device as described herein.

Certain embodiments of the present disclosure provide a method of generating electricity. Methods for generating electrical energy are as described herein.

In certain embodiments, the present disclosure provides a method of generating electrical energy, the method comprising:
producing an electric potential difference using an asymmetric pair of metal-semiconductor junctions;
producing charge carriers within the semiconductor by thermal excitation, the charge carriers being mobile under the effect of an electric field; and
capturing the charge carriers into an external circuit using the electrical potential difference;
thereby generating electrical energy.

In certain embodiments, the present disclosure provides a method of generating electrical energy, the method comprising:
producing an electric potential difference between first and second closely spaced electrodes, the first electrode comprising a low work function metal material and the second electrode comprising a high work function metal material;
producing charge carriers within a semiconductor disposed between the electrodes by thermal excitation, the charge carriers being mobile under the effect of an electric field; and
capturing the charge carriers into an external circuit using the electric field existing between the electrodes;
thereby generating electrical energy.

In certain embodiments, the present disclosure provides a method of generating electrical energy, the method comprising:
producing an electric field between first and second closely spaced electrodes, the first electrode comprising a low work function metal material and the second electrode comprising a high work function metal material, the electric field being produced due to different types of metal-semiconductor junctions at the two different electrodes;
producing charge carriers by thermal excitation, the charge carriers being mobile under the effect of an electric field; and
capturing the charge carriers into an external circuit using the electric field existing between the electrodes;
thereby generating electrical energy.

Certain embodiments of the present disclosure provide a device for generating electrical energy using a method as described herein.

Certain embodiments of the present disclosure provide a method of producing an electrical generating device.

In certain embodiments, the present disclosure provides a method of producing an electrical energy generating device, the method comprising incorporating an asymmetric pair of metal-semiconductor junctions into the device, wherein the semiconductor is capable of producing charge carriers in response to thermal excitation.

Certain embodiments of the present disclosure provide a method of producing an electrical energy generating device, the method comprising incorporating one or more electrical cells into the device, the one or more electrical cells comprising first and second closely spaced electrodes, the first electrode comprising a low work function metal material and the second electrode comprising a high work function metal material, and disposed between the first and second electrodes a semiconductor capable of producing charge carriers in response to thermal excitation.

Certain embodiments of the present disclosure provide a device produced by a method as described herein.

The present disclosure is further described by the following examples. It is to be understood that the following description is for the purpose of describing particular embodiments only and is not intended to be limiting with respect to the above description.

### EXAMPLE 1—Production and Testing of Thermovoltaic Devices

A thermovoltaic proof-of-concept experiment was conducted to test tailored asymmetric metal-semiconductor-metal (AMSM) ‘sandwich’ structures to measure the effectiveness of collecting thermally induced charge-carriers in germanium (Ge: band-gap ˜0.7 eV), using a built-in electric field.

A number of AMSM structures were fabricated on standard glass slides with the following compositional arrangement: nickel metal (150 nm thick)|germanium (500 nm thick)|samarium (200 nm thick)|copper (150 nm thick). The copper layer was used only as a protective yet conductive film for the easily oxidised samarium. The glass slide served only as a supporting substrate.

Each of the layers was deposited in a versatile physical vapour deposition system comprising multiple target crucibles containing the respective coating materials in their elemental form. The crucibles were heated with a high energy scanned electron beam. The system operates under vacuum with a typical pressure of 2×10⁻⁶ bar. The deposition frame on which the glass substrates were fixed was located about 30 cm above the crucible surface and it was heated to around 100° C. to help minimise stresses in the deposited films. The system was also fitted with an inert gas ion gun directed at the deposition surface, in order to minimise deposited film porosity. The film deposition rates ranged between 0.2 nm/sec (for Ni) to 1 nm/sec (for Sm). The AMSM structures were made by first depositing a nickel or samarium film, then opening the deposition chamber and masking off a region with kapton tape before readmitting the slide into the chamber and depositing the remaining two films, without breaking system vacuum. When the kapton tape was removed it exposed an electrode surface to which connections could be easily made. Film quality was assessed by eye at each point during the deposition sequence and for all fabricated AMSM structures the metal surfaces appeared highly uniform, reflective and were defect free.

A separate group of device structures was fabricated in which germanium was replaced by a semiconducting polymer composite—polyaniline-nylon—as the thermal excitation/charge-collection medium. Films of this composite were prepared directly on nickel electrodes by drop-casting small amounts of polyaniline-Nylon ‘inks’—these being dispersions of a fine powder of polyaniline (in its emeraldine-salt form (PANI-ES)) in a solution of Nylon-6 in 90% ww formic acid.

The resulting films had thicknesses in the 10-25 micron range and they had high electrical conductivities. The PANI-ES-Nylon inks were made by combining finely ground PANI-ES powder with a Nylon-6-formic acid solution that had been separately prepared by mixing Nylon-6 wire pieces and 90% ww formic acid in a sealed vial at 50° C. for about 30 minutes. The PANI-ES had been ground in a small agate mortar and pestle. Weighed amounts of the resulting powder were placed in glass vials to which weighed amounts of the nylon solution were added, such that the PANI-ES content was ˜80% ww. After combining the PANI-ES powder and the nylon solution, the ink mixture was manually mixed, taking care to avoid introducing too many air bubbles. The nickel electrodes were prepared using the process and equipment as described above, such that they had a thickness of ˜250 nm. The drop-cast polyaniline-Nylon films on the nickel electrodes were coated with samarium metal ‘top’ electrodes, and a copper protective layer in a single run in the vacuum coating apparatus as described.

A structure comprising Sm|PEDOT-PSS|Ni was also prepared and tested. The poly(3,4-ethylenedioxythiophene) polystyrene sulfonate (PEDOT:PSS) polymer was obtained as a dispersion from a commercial source and deposited to produce a layer of 4 microns thick.

A structure comprising two symmetric electrodes was also fabricated in a similar manner as described above, namely a structure with the form Ni|Ge|Ni, to enable a ‘blank’ test of the thermovoltaic response where there is no built-in electric field, due to the symmetric nature of the junctions.

Thermovoltaic (TV) tests of the candidate device structures were carried out by placing the test-pieces on a temperature-controlled hot-plate and connecting each electrode to a digital multimeter comprising a high impedance voltmeter (Agilent DMM 2345) with flat-jaw alligator clips. The multimeter also served as a sensitive ammeter (sensitivity ˜10 nA). The hotplate was heated in several steps of 25° C. or 50° C. to nominal temperatures between 90° C. and 325° C. ‘Real’ surface temperatures were periodically measured using a non-contact IR probe, indicating that the test-pieces were at 15° C.-30° C. lower than nominal. The current and cell voltage values were each manually recorded when the readings appeared stable.

The results are shown Table 1, which shows a listing of thermally-driven current measurements carried out on the candidate thermovoltaic structures.

TABLE 1

| | |
|---|---|
| Max | Max |
| Thermally | Thermally- |
| Excited | Excited |
| Voltage | Current |
| (V) | (μA) |

Sm | Germanium | Ni AMSM Structure Specimens

| | | |
|---|---|---|
| Device-1 - nominal 225° C. | not measured | 350 |
| Device-2 - nominal 225° C. | ~0.43 | 2.7 |
| Device-2 - nominal 325° C. | 0.93 | 3.7-3.8 |

Sm | PANI-Nylon6 | Ni AMSM Structure Specimens

| | | |
|---|---|---|
| Device-1 (~5 cm² area) nominal 250° C. | ~0.47 | 290-300 |
| Device-2 (~4 cm² area) nominal 250° C. | ~0.44 | 140 |

Sm | PEDOT-PSS | Ni AMSM Structure Specimen

| | | |
|---|---|---|
| Device-1 - nominal 210° C. | 0.35 | 480-520 |

Ni | PANI-Ny6 | Ni Symmetric Structure Specimen

| | | |
|---|---|---|
| Device-1 - nominal 270° C. | ~0.01 | 0.4-0.8 |

It is apparent from the electric outputs measured from the thermovoltaic devices that significant levels of power can be collected from the devices-as-a-whole, indeed the power generation level from the second Sm|PANI-Nylon|Ni device corresponds to 16 μWcm⁻¹. This in turn means that charge carrier collection must be rather efficient which seems attributable at least in part to effective electric fields in place at the (asymmetric) electrode junctions.

These findings also demonstrate that thermovoltaic devices can produce useful power outputs at relatively low temperatures. Their thin nature indicates that generating cells of this type could be stacked and connected in reasonable numbers.

### EXAMPLE 2—Production of Thermovoltaic Devices Using a Compound Group III-V Semiconductor

The thermovoltaic electric power generating arrangement described in Example 1 may also be extended to exploit low band-gap semiconductors that are available commercially in high purity wafer form.

Indium arsenide (InAs) and indium antimonide (InSb) are prospective thermovoltaic III-V semiconductors having small band-gaps of 0.35 eV and 0.2 eV respectively, and they manifest good charge-carrier mobility upon electronic excitation (eg, by photons).

Thin InAs wafers having thicknesses in the range of 50-100 μm can be produced by a method known in the art, or can be prepared by abrading and polishing commercially available thicker wafers down to a desired thickness. Standard polishing methods can be used in this regard.

Wafers of InAs or InSb produced with the aforementioned techniques can be coated with low work-function metal electrodes (eg, samarium) using a vacuum deposition apparatus as described in Example 1. Metal electrode thicknesses of at least 200 μm are appropriate to ensure device robustness.

Thermovoltaic structures based on InAs as an archetypical III-V semiconductor may be electrically characterised by securely connecting each electrode to a conductive lead that is sufficiently long and robust to allow the test device to reside in an oven or furnace for an extended period, while being connected at their other end to a sensitive digital multimeter, picoammeter and/or a potentiostat capable of sweeping interelectrode potential while cell current is measured.

Cell voltages and currents produced by the InAs test devices may then be measured as function of temperature as the temperature of the oven/furnace chamber is gradually increased. In order to correct for thermoelectric (Seebeck effect) signal artifacts such as potentials arising in the characterisation system (eg, due to the temperature difference along the leads) a number of ‘dummy’ structures can be made comprising a fully conducting material between the two different electrodes, but otherwise retaining the same measurement architecture. Electrical output readings recorded from such a structure may be subtracted from those of the device being tested.

### EXAMPLE 3—Production of Thermovoltaic Devices Using a Compound Group VI Semiconductor

The thermovoltaic electric power generating arrangement described in Example 1 may also be extended to exploit low band-gap semiconductors that are available commercially in high purity polycrystalline form suitable for being formed into uniform thin slabs or films.

Thallium selenide (TlₓSe) are prospective thermovoltaic Group-VI-containing semiconductors having a band-gaps in the range of ˜0.5-0.8 eV and good charge-carrier mobility upon electronic excitation (eg, by photons).

Pure thallium selenide powders with narrow particle size distribution can be prepared by grinding and sieving lump-form Tl₂Se from commercial suppliers (eg, Alfa Aesar). Tl₂Se powders with average particle sizes of between 0.8-20 μm may be prepared and may be subsequently formed into uniform thin slabs or films by, for example: (i) mixing a Tl₂Se powder with a suitable polyamide (eg, nylon-6) powder and heating the resulting blend in a vacuum to about 220° C. at which point the hot composite can be extruded or press-formed into ribbons or sheets 10-80 μm thick; (ii) dispersing a Tl₂Se powder into a solution of a suitable binding polymer (eg, polyetherimide) in a suitable solvent (eg, chloroform) and then coating the resultant free-flowing but viscous mixture directly onto an electrode (eg, nickel) using a spin-coating or drop-casting method that allows for controlled uniform film deposition in the 4-20 μm thickness range; (iii) press-forming Tl₂Se powder directly onto a flat electrode (eg, nickel) surface using a PTFE-coated ram onto a thin PTFE die while the electrode is heated to ˜40° C. below the melting temperature of Tl₂Se (˜380° C.), thereby sintering the compound into a thin slab with thickness being controlled mainly by the pressure and the mass of Tl₂Se. For cases (i) and (ii) it is envisaged that the Tl₂Se-polymer composites will contain a high mass loading of the inorganic component to ensure that no Tl₂Se within the film is electrically isolated.

An exposed side of slabs or films of Tl₂Se produced with aforementioned techniques can be coated with a low work-function metal electrode (eg, samarium) using a vacuum deposition apparatus as described in Example 1, noting that for experimental thermovoltaic structures made using extruded polymer-Tl₂Se composites in ribbon/sheet form, it is necessary to also coat a high work function metal electrode (eg, nickel) on the opposite surface. Metal electrode thicknesses of at least 200 μm are appropriate to ensure device robustness.

Experimental thermovoltaic structures based on Tl₂Se as an archetypical Group-VI-containing semiconductor can be electrically characterised by securely connecting each electrode to a conductive lead that is sufficiently long and robust to allow the test device to reside in an oven or furnace for an extended period, while being connected at their other end to a sensitive digital multimeter, a picoammeter and/or a potentiostat capable of sweeping interelectrode potential while cell current is measured. Cell voltages and currents produced by the Tl₂Se test devices may then be measured as function of temperature as the temperature of the oven/furnace chamber is gradually increased. In order to rule out and/or correct for thermoelectric (Seebeck effect) signal artifacts such as potentials arising in the characterisation system (eg, due to the temperature difference along the leads) a number of ‘dummy’ structures can be made comprising a fully conducting material between the two different electrodes, but otherwise retaining the same measurement architecture. Electric output readings recorded from such a structure may be subtracted from those of the device being tested.

### EXAMPLE 4—Production of Thermovoltaic Devices Using a Heat Generated from a Radioactive Isotope

The thermovoltaic electric power generating system described in Example 3 may be extended to incorporate an amount of the ²⁰⁴Tl radioisotope into the Tl₂Se used as the low band-gap semiconductor in which charge-carriers are produced and in which an in-built electric potential exists, enabling charge carriers to be swept into an external electric circuit. Methods for incorporating ²⁰⁴Tl radioisotopes into Tl₂Se are known in the art.

Benefits deriving from incorporating ²⁰⁴Tl into Tl₂Se for thermovoltaic devices include: (i) providing an additional means for exciting charge-carriers within the semiconductor since each beta-particle emission from this radioisotope carries hundreds of keV energy and is thus able to create many electron-hole pairs; (ii) providing an internal source of heat associated with the radioactive decay of ²⁰⁴Tl, with this heat contributing a small boost to charge-carrier mobility in the Tl₂Se thus enhancing overall efficiency, and the heat can also provide system robustness for devices operating in extremely cold environments such as space.

Although the present disclosure has been described with reference to particular examples, it will be appreciated by those skilled in the art that the disclosure may be embodied in many other forms.

It is to be understood that various alterations, additions and/or modifications may be made to the parts previously described without departing from the ambit of the present disclosure, and that, in the light of the above teachings, the present disclosure may be implemented in software, firmware and/or hardware in a variety of manners as would be understood by the skilled person.

As used herein, the singular forms “a,” “an,” and “the” may refer to plural articles unless specifically stated otherwise.

Throughout this specification, unless the context requires otherwise, the word “comprise”, or variations such as “comprises” or “comprising”, will be understood to imply the inclusion of a stated element or integer or group of elements or integers but not the exclusion of any other element or integer or group of elements or integers.

All methods described herein can be performed in any suitable order unless indicated otherwise herein or clearly contradicted by context. The use of any and all examples, or exemplary language (e.g., “such as”) provided herein, is intended merely to better illuminate the example embodiments and does not pose a limitation on the scope of the claimed invention unless otherwise claimed. No language in the specification should be construed as indicating any non-claimed element as essential.

The description provided herein is in relation to several embodiments which may share common characteristics and features. It is to be understood that one or more features of one embodiment may be combinable with one or more features of the other embodiments. In addition, a single feature or combination of features of the embodiments may constitute additional embodiments.

The subject headings used herein are included only for the ease of reference of the reader and should not be used to limit the subject matter found throughout the disclosure or the claims. The subject headings should not be used in construing the scope of the claims or the claim limitations.

Future patent applications may be filed on the basis of the present application, for example by claiming priority from the present application, by claiming a divisional status and/or by claiming a continuation status. It is to be understood that the following claims are provided by way of example only, and are not intended to limit the scope of what may be claimed in any such future application. Nor should the claims be considered to limit the understanding of (or exclude other understandings of) the present disclosure. Features may be added to or omitted from the example claims at a later date.

1. An electrical energy generating device, the device comprising a plurality of electrical cells, each cell comprising an asymmetric pair of metal-semiconductor junctions to produce an electric potential difference to capture thermally excited charge carriers within the semiconductor, wherein the asymmetric pair of metal-semiconductor junctions is formed from two closely-spaced electrodes of different composition in contact with the semiconductor, one of the electrodes comprising a low work function metal material and the other electrode comprising a high work function metal material,
wherein the semiconductor is a low band-gap semiconducting material, and
wherein the charge carriers are excited by conductively delivered heat to the semiconductor in each cell.

2. (canceled)

3. The electrical energy generating device according to claim 1, wherein the low work function metal material comprises one or more of europium, strontium, barium, samarium, dysprosium, neodymium, gadolinium, terbium, holmium, erbium, thulium, lanthanum, scandium, thorium, calcium, magnesium, cerium, yttrium, ytterbium, sodium, lithium, potassium, rubidium, hafnium, and cesium.

4. The electrical energy generating device according to claim 1, wherein the low work function metal material comprises samarium metal.

5. The electrical energy generating device according to claim 1, wherein the high work function metal material comprises one or more of nickel, platinum, silver, gold, aluminium, cobalt, chromium, copper, beryllium, bismuth, cadmium, iron, gallium, germanium, mercury, indium, iridium, manganese, molybdenum, niobium, osmium, lead, palladium, rhenium, rhodium, ruthenium, antimony, silicon, tin, tantalum, technetium, titanium, vanadium, tungsten, zinc and zirconium.

6. The electrical energy generating device according to claim 5, wherein the high work function metal material comprises nickel metal.

7. (canceled)

8. The electrical energy generating device according to claim 1, wherein the semiconductor has a band gap of less than 1.1 eV.

9. The electrical energy generating device according to claim 1, wherein the semiconductor comprises one or more of a Group IV semiconductor, a Group III-V compound semiconductor, and a semiconductor containing a Group VI element as a major constituent.

10. The electrical energy generating device according to claim 9, wherein the Group IV semiconductor comprises germanium, doped germanium, a germanium-tin alloy or intermetallic compound, a germanium-silicon alloy or intermetallic compound, silicon, doped silicon, and a silicon-tin alloy or intermetallic compound.

11. The electrical energy generating device according to claim 9, wherein the Group III-V compound semiconductor comprises a pure nitride, phosphide, arsenide, antimonide or bismuthide of one or more of aluminium, gallium, indium, and thallium, or is a mixed nitride, phosphide, arsenide, antimonide, or bismuthide of one or more of aluminium, gallium, indium, and thallium.

12. The electrical energy generating device according to claim 9, wherein the semiconductor containing a Group VI element as a major constituent comprises elemental selenium, or a compound semiconductor comprising a pure oxide, sulfide, selenide, or telluride, or a mixed oxide, sulfide, selenide, or telluride.

13. The electrical energy generating device according to claim 1, wherein the semiconductor comprises thallium sulfide, thallium selenide, thallium telluride, or a doped version thereof.

14. The electrical energy generating device according to claim 1, wherein the semiconductor comprises a polymer blended with the semiconductor.

15. The electrical energy generating voltaic device according to claim 14, wherein the polymer comprises a conducting polymer.

16. The electrical energy generating device according to claim 15, wherein the conducting polymer comprises one or more of a polythiophene, a polyacetylene, a polyphenylene vinylene, a polyphenylene sulphide, a polyaniline, a polyvinylacetylene, a polypyrrole, a polyindole, a polyvinylene, a polyazulene, a polyselenophone, and an organo-boron polymer.

17. The electrical energy generating device according to 14, wherein the polymer comprises an inert polymer.

18. The electrical energy generating device according to claim 17, wherein the inert polymer comprises one or more of a nylon, a polyimide, a polytetrafluoroethylene, a polypropylene, a polyethylene, a polyvinyl chloride, a polyacrylonitrile, and a polyurethane.

19. The electrical energy generating device according to claim 1, wherein the semiconductor comprises a semiconducting polymer.

20. The electrical energy generating device according to claim 19, wherein the semiconducting polymer comprises one or more of a polythiophene, a polyacetylene, a polyphenylene vinylene, a polyphenylene sulphide, a polyaniline, a polyvinylacetylene, a polypyrrole, a polyindole, a polyvinylene, a polyazulene, a polyselenophone, and an organo-boron polymer.

21. The electrical energy generating device according to claim 1, wherein the first and second electrodes are separated by a distance in the range from 0.3 to 100 micrometres.

22-23. (canceled)

24. The electrical energy generating device according to claim 1, wherein the device comprises a radioactive isotope incorporated into the device.

25. (canceled)

26. The electrical energy generating device according to claim 1, wherein the electrical cells are electrically connected in series or in parallel.

27-30. (canceled)

31. A method of generating electrical energy, the method comprising:
producing an electric field between first and second closely spaced electrodes of one of a plurality of electrical cells, the first electrode comprising a low work function metal material and the second electrode comprising a high work function metal material, the electric field being produced due to different types of metal-semiconductor junctions at the two different electrodes;
producing charge carriers within a semiconductor disposed between the electrodes by thermal excitation, wherein the semiconductor is a low band-gap semiconducting material and wherein the charge carriers are excited by conductively delivered heat to the semiconductor in each cell; and
capturing the charge carriers into an external circuit using the electric field existing between the electrodes;
thereby generating electrical energy.

32-35. (canceled)
